(19) United States
(12) Patent Application Publication
(10) Pub. No.: US 2026/0318989 A1
(43) Pub. Date: Oct. 15, 2026

(54) CIRCUIT TESTING METHOD AND CIRCUIT TESTING SYSTEM

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventor: Chen-Yuan KAO, HSINCHU CITY (TW)

(21) Appl. No.: 19/251,853

(22) Filed: Jun. 27, 2025

(30) Foreign Application Priority Data
Apr. 14, 2025 (TW) 114113980

(51) Int. Cl. G01R 31/3177

(52) U.S. Cl. CPC G01R 31/3177

(57) ABSTRACT

A circuit testing method, comprising: obtaining a test data of an integrated circuit comprising multiple logic circuits and multiple memory circuits; analyzing the test data to cluster each memory circuit into one of multiple test groups, wherein multiple first memory circuits are clustered into a first test group; and generating a test signal and multiple control signals according to a clustering result of the memory circuits and the test data, wherein the test signal is configured to perform the scan test on the integrated circuit, the control signals are configured to control the first memory circuits, so that when performing the scan test, a number of the first memory circuits enabled simultaneously is limited to be less than a first enable count limit.

### CROSS-REFERENCE TO RELATED APPLICATION

This application claims priority to Taiwan Application Serial Number 114113980, filed Apr. 14, 2025, which is herein incorporated by reference in its entirety.

### BACKGROUND

### Technical Field

The present disclosure relates to testing of integrated circuits, and more particularly to a circuit testing method and a circuit testing system.

### Description of Related Art

Scan Test is a testing technique applied to integrated circuit (IC) to detect abnormalities or damaged logic circuits within the integrated circuit. As chip design complexity increases, the process of identifying potential defects in the integrated circuit by scan test has become increasingly important, and is also a necessary step in ensuring circuit reliability and performance.

### SUMMARY

One aspect of the present disclosure is a circuit testing method, comprising: obtaining a test data of an integrated circuit, wherein the integrated circuit comprises a plurality of logic circuits and a plurality of memory circuits, and the test data is configured to record at least one test feature of the plurality of logic circuits and the plurality of memory circuits when performing a scan test; analyzing the test data to cluster each of the plurality of memory circuits into one of a plurality of test groups, wherein a plurality of first memory circuits of the plurality of memory circuits is clustered into a first test group of the plurality of test groups; and generating a test signal and a plurality of control signals according to a clustering result of the plurality of memory circuits and the test data, wherein the test signal is configured to perform the scan test on the integrated circuit, the plurality of control signals are configured to control the plurality of first memory circuits, so that when performing the scan test, a number of the plurality of first memory circuits enabled simultaneously is limited to be less than a first enable count limit.

Another aspect of the present disclosure is a circuit testing system, comprising a plurality of memory circuits, a plurality of logic circuits and a plurality of logic circuits. The plurality of memory circuits are respectively clustered into one of a plurality of test groups. A plurality of first memory circuits of the plurality of memory circuits are clustered into a first test group of the plurality of test groups. The plurality of logic circuits are coupled to the plurality of memory circuits. The plurality of control circuits are coupled to the plurality of memory circuits. Each of the plurality of control circuits selectively enables or disables a corresponding one of the plurality of memory circuits. When performing a scan test, the plurality of control circuits are configured to receive a plurality of control signals to control a number of the plurality of first memory circuits enabled simultaneously is limited to be less than a first enable count limit.

Another aspect of the present disclosure is a circuit testing method, comprising: obtaining a test data of an integrated circuit, wherein the integrated circuit comprises a plurality of logic circuits and a plurality of memory circuits, and the test data is configured to record at least one test feature of the integrated circuit when performing a scan test; classifying each of the plurality of memory circuits into one of a plurality of test categories according to the test data, wherein a portion of the plurality of memory circuits belonging to a same time domain into a same one of the plurality of test categories; clustering each of the plurality of memory circuits into one of a plurality of test groups according to the test data and the plurality of test categories; and generating a plurality of control signals corresponding to the plurality of memory circuits according to the test data and the plurality of test groups, so that when performing the scan test, an operating state of the plurality of memory circuits is selectively controlled by the plurality of control signals.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of an integrated circuit in some embodiments of the present disclosure.

FIG. 2 is a schematic diagram of a circuit testing system in some embodiments of the present disclosure.

FIG. 3 is a flowchart illustrating a circuit testing method in some embodiments of the present disclosure.

FIG. 4A is a schematic diagram of the operation of the processing circuit in some embodiments of the present disclosure.

FIG. 4B is a schematic diagram of the cluster and the classification in some embodiments of the present disclosure.

FIG. 5 is a schematic diagram of the circuit testing system in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes associated listed items or any and all combinations of more.

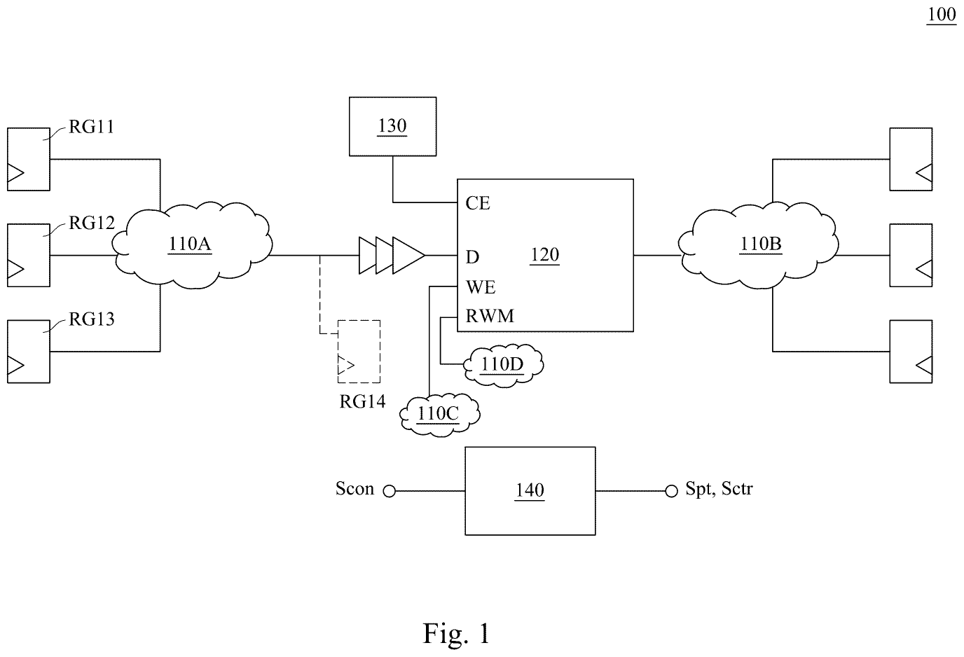

The present disclosure relates to a circuit testing system and a circuit testing method applied to an integrated circuit, which is configured to perform a scan test on the integrated circuit. To facilitate understanding of the application of the present disclosure, the integrated circuit 100 shown in FIG. 1 is used as an example to describe the operation of the scan test as follows.

Refer to FIG. 1, the integrated circuit 100 includes multiple logic circuits and multiple memory circuits. The logic circuits, such as 110A-110D shown in FIG. 1, may includes one or more logic elements. According to the functions of different circuits, the composition and circuit architecture of the logic circuits will be different. Since those skilled in the art can understand the meaning of the logic circuit, they are not further detailed herein.

The memory circuits, such as RG11-RG13 and 120 shown in FIG. 1, can be implemented by Flip-flop (e.g., D-Flip-flop). To describe the embodiments of the present disclosure in subsequent paragraphs, different numbers are assigned herein to represent memory circuits. Taking the memory circuit 120 as an example, the memory circuit 120 includes an input terminal D, a read/write control terminal WE, an enabling control terminal CE, and a read/write margin control terminal RWM. The input terminal D, the read/write control terminal WE, and the read/write margin control terminal RWM are respectively coupled to the logic circuits 110A, 110C, and 110D, and the output terminal of the memory circuit 120 is coupled to the logic circuit 110B.

Scan Test is a technique used to detect circuit abnormalities in the integrated circuit. In one embodiment, a test signal Spt (Pattern) is generated by a processing circuit 140, ans is used to the input data for the scan test. The processing circuit 140 may generate the test signal Spt using Automatic Test Pattern Generation (ATPG) technology. The “processing circuit” may be a testing machine, a signal processor, or a computer device configured to generate signals, and the present disclosure does not limit this.

To facilitate understanding, the process of the scan test is described as follows. Taking FIG. 1 as an example, if the test target of the scan test is the logic circuit 110A, an additional bypass logic RG14 (e.g., register) needs to be configured between the logic circuit 110A and the memory circuit 120 during the scan test, so as to read the test result.

The testing process of the scan test includes “Shift mode” and “Capture mode”. In the shift mode, the test signal Spt is sequentially input to the logic circuit 110A through the register according to the clock signal. The process of data input with the clock signal is called “Shift”. In the capture mode, the clock signal is stopped, and after the logic circuit 110A completes the corresponding logical operation, the clock signal is restored to output the operation result of the logic circuit 110A to the bypass logic RG14. The process of outputting the result to the bypass logic RG14 after the operation is called “Capture”.

However, in some integrated circuit products, bypass logic may not be configured due to design constraints (e.g., insufficient space), and it makes the scan test unable to execute. Refer to FIG. 1, although there is a memory circuit 120 arranged between the logic circuits 110A and 110B and unused during the scan test, it is not suitable for recording the scan test results. The reason is that if multiple memory circuits (e.g., the memory circuit 120) in the integrated circuit 100 are simultaneously enabled to record the test results during the scan test, the current will significantly increase, causing a corresponding rise in voltage across the electronic components in the integrated circuit 100. Therefore, it may lead to power supply instability, resulting in potential operational errors or abnormalities in some electronic components, known as “IR-drop issue.”

The present disclosure configures a control circuit 130 in the integrated circuit 100 (e.g., couples to the enabling control terminal CE of the memory circuit 120) to control the memory circuit 120. By controlling the enable or disable timing of the memory circuit 120, the memory circuit 120 can be used to record the result of the scan test. Accordingly, there is no need to additionally configure the bypass logic, and will not have to worry about the IR-drop issue.

Specifically, when the processing circuit 140 generates the test signal Spt, the processing circuit 140 also generates the corresponding control signal Sctr for each control circuit 130 according to a constraint data Scon. By modifying the logical level of the enabling control terminal CE, the operating state of the memory circuit 120 (i.e., enable or disable) will be set. The definition and generation method of the constraint data Scon will be detailed in subsequent paragraphs.

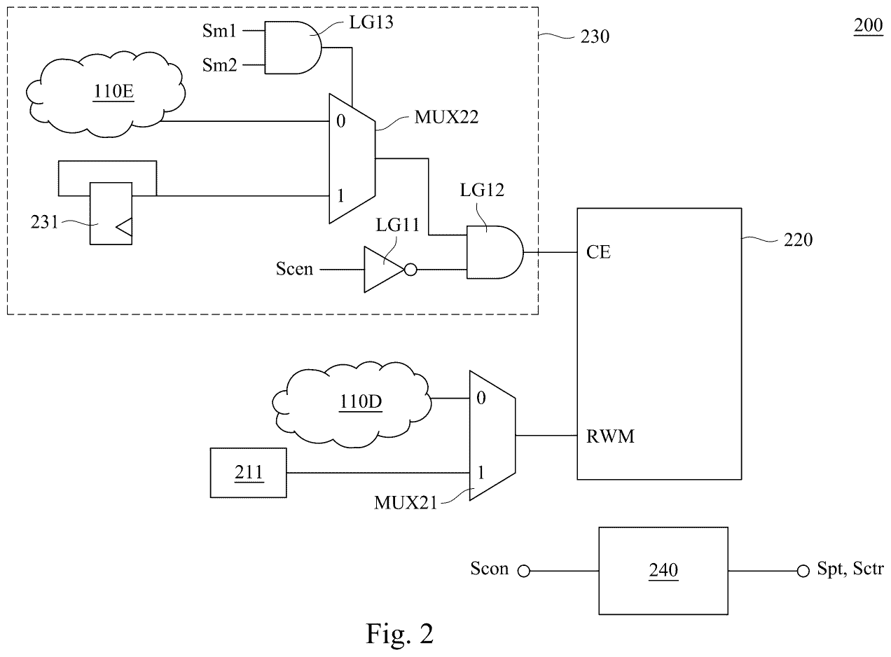

FIG. 2 is a schematic diagram of a circuit testing system 200 in some embodiments of the present disclosure. The circuit testing system 200 can be applied to the integrated circuit shown in FIG. 1. The embodiment described in FIG. 2 does not change the operation of FIG. 1, in which the logic circuits 110A and 110C receive the test signal Spt to perform the scan test. Therefore, in order to keep the diagram simple for ease of explanation, FIG. 2 omits the logic circuits coupled to the input terminal D, the read/write control terminal WE, and the corresponding logic circuits. The memory circuit 220 may correspond to the memory circuit 120 shown in FIG. 1. The control circuit 230 may correspond to the control circuit 130 shown in FIG. 1.

The circuit testing system 200 includes multiple logic circuits (FIG. 2 shows only 110D and 110E), multiple memory circuits (FIG. 2 shows only 220) and multiple control circuits (FIG. 2 shows only 230). In this embodiment, the read/write margin control terminal RWM of the memory circuit 220 is respectively coupled to the logic circuit 110D and the configuration circuit 211 through the multiplexer MUX21. The configuration circuit 211 provides read/write setting signals to set the speed of the memory circuit 220 when operating in read or write mode.

The control circuit 230 includes a register 231, a multiplexer MUX22 and multiple logic gates LG21-LG23 (as the AND gate and the inverter shown in FIG. 2). The logic gates LG21-LG23 respectively receive the enable signal Scen (scan_enable) and the mode signals Sm1/Sm2 to selectively modify the level of the output signal of the control circuit 230, thereby controlling the enable or disable of the memory circuit 220. The enable signal Scen and the mode signals Sm1/Sm2 may be the previously mentioned control signal Sctr or at least a portion thereof.

Refer to the table below, which shows the signal states of the circuit testing system 200 in different modes (“X” represents “don't care”). The “functional mode” refers to the normal operation of the integrated circuit rather than performing the scan test.

| Mode | Signal Sm1 | Signal Sm2 | Signal Scen |
|---|---|---|---|
| Functional mode | X | 0 | 0 |
| Shift mode | X | 1 | 1 |
| Capture mode | 1 | 1 | 0 |

As shown in the table above, in the functional mode, the multiplexer MUX22 selects the signal from the logic circuit 110E as the output signal. Therefore, at this time, the circuit testing system 200 is not performing the scan test. In the shift mode, since the enable signal Scen is “1,” after being inverted by the logic gate LG21, the level of the output signal of the logic gate LG22 becomes “0,” causing the memory circuit 220 to be disabled. On the other hand, in the capture mode, the level of the output signal of the logic gate LG22 is “1,” causing the memory circuit 220 to be enabled. It should be noted that the control circuit 230 is not limited to this embodiment, and the circuit shown in FIG. 2 is merely one example.

The present disclosure generates the test signal Spt and multiple control signals Sctr corresponding to the multiple memory circuits according to the test data of the integrated circuit. The control circuit 230 selectively controls the operating state of the memory circuit 220 during the scan test according to the corresponding control signal Sctr, such as disabling read/write state, read state, or write state. The test data includes at least one test feature recorded during the scan test, which can reflect the circuit characteristics or configuration of the integrated circuit (e.g., the logic circuits or the memory circuits). In some embodiments, the test data may include one or more of the following four types:
(1) Netlist data: the netlist data is configured to record a connection relationship between multiple logic circuits and multiple memory circuits in the integrated circuit. Specifically, the netlist data records the electrical connection relationship between circuit components in a specific format, such as the identifier of the electronic component.
(2) Timing Constraints data: the timing constraints data (e.g., Synopsys Design Constraints (SDC) data) is configured to record the clocks of the integrated circuit (memory circuits and logic circuits). Specifically, the timing constraints data uses a special data format to record the operating characteristics of each logic circuit in the integrated circuit to ensure that the expected performance can be achieved when running the circuit.
(3) Library data: the library data is configured to record the logic characteristic or power consumption of the memory circuits and each logic circuit, such as the circuit components or the operating characteristic including multiple different logic elements.
(4) Design Exchange Format (DEF) data: the design exchange format data is configured to record a layout structure of the integrated circuit. Specifically, the design exchange format data uses a specialized format to describe the physical design of the integrated circuit, so as to record the layout design, component positions, and connection paths.

In this embodiment, the circuit testing system 200 includes a processing circuit 240 to obtain the test data (e.g., couples to the integrated circuit to detect data, or input file by the tester). The circuit testing system 200 classifies each memory circuit 220 into one of multiple test categories, and/or clusters each memory circuit 220 into one of multiple test groups according to the test data. Based on the analysis result of classification and clustering, the processing circuit 240 first generates the constraint data Scon, and then used the constraint data Scon to generate the test signal Spt required for the scan test and to provide the control signal(s) Sctr to each control circuit 230. In other embodiments, the test data may first be obtained by another processor and generates the constraint data Scon. Then, inputting the constraint data Scon into the processing circuit 240 to generate the test signal Spt and the control signal(s) Sctr.

As mentioned above, the classification and clustering are determined according to “whether multiple memory circuits need to operate simultaneously during the scan test”. For example, determining whether the operations of the logic circuits corresponding to multiple memory circuits are interrelated, whether the logic circuits belong to the same scan chain, or whether the logic circuits belong to the same time domain (clock domain) or use the same clock signal. Therefore, memory units that need to operate simultaneously during the scan test (e.g., belong to the same time domain) to record test results are classified to the same test category.

On the other hand, memory units that do not need to operate simultaneously during the scan test to record test results are clustered into the same test group. It should be noted that, in one embodiment, one test group may include a certain number of memory circuits that operate simultaneously, which is referred to as “enable count limit.” In other words, within the same test group, the number of memory circuits enabled simultaneously is controlled to remain below the enable count limit. For example, the first test group includes 30 first memory circuits, and a first enable count limit for the first test group is “2.” During the scan test, the control circuit controls the first memory circuits according to the control signal Sctr, ensuring that the number of the first memory circuits enabled simultaneously is limited to be less than 2 (first enable count limit). The enable count limit is determined according to the power supply capacity or energy consumption constraints of the integrated circuit, and may be set to 1, 2, or 5, but the present disclosure is not limited to these values.

The control signal generated in the aforementioned manner can control the number of memory circuits enabled simultaneously during the scan test. This can avoid the IR-drop issue caused by the multiple memory circuits being enabled at the same time, which would cause the current to rise. Accordingly, the memory already configured within the integrated circuit can be used as the register during the scan test, without configuring bypass logic additionally.

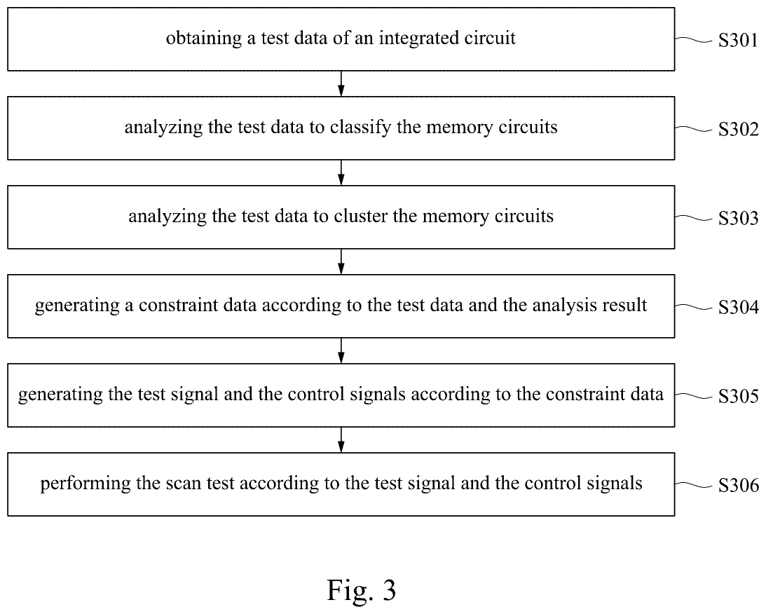

FIG. 3 is a flowchart illustrating a circuit testing method in some embodiments of the present disclosure, which can be applied to the integrated circuit 100 shown in FIG. 1 or the circuit testing system 200 shown in FIG. 2. Using a flowchart as an example to explain the operational concept of the present disclosure. In step S301, the processing circuit 240 first obtains a test data of the integrated circuit. As previously mentioned, the test data may include one or more of the following: the netlist data, the timing constraints data, the library data, and the design exchange format data.

In step S302, the processing circuit 240 analyzes the test feature within the test data to classify each memory circuit into one of multiple test categories. As previously mentioned, memory circuits that need to operate simultaneously during the scan test (e.g., belong to the same time domain) to record test results are classified to the same test category.

In step S303, the processing circuit 240 analyzes the test feature within the test data, and further clusters the multiple memory circuits into one of the multiple test groups according to the classifying result from step S302. In one embodiment, the memory circuits within the same test group may all be categorized as “not required to operate simultaneously during the scan test”. For example, multiple memory circuits belonging to different time domains (i.e., a portion of all memory circuits) may be clustered into the same test group. In another embodiment, the memory circuits within the same test group must meet the condition that “the number of simultaneously enabled memory circuits during the scan test must be less than the enable count limit.”

In step S304, according to the test data and the analysis result (i.e., the clustering result and/or classifying result), the processing circuit 240 organizes the constraint data Scon. Specifically, the processing circuit 240 analyzes the memory enable count limits of the test groups according to the physical areas corresponding the test groups (i.e., the layout location within the integrated circuit). Then, according to the test data, the analysis result, and/or the memory enable count limit, generating the constraint data Scon.

In step S305, according to the constraint data Scon, the processing circuit 240 generates the test signal Spt for performing the scan test and the control signal Sctr providing to each control circuit.

In step S306, the integrated circuit performs the scan test according to the test signal Spt and the control signal Sctr. For example, the test signal Spt is provided to the logic circuit 110A shown in FIG. 1, while the control signal Sctr is provided to the control circuit 130 shown in FIG. 1. Specifically, in the shift mode of the scan test, the control circuit disables the corresponding memory circuit according to the clock signal corresponding to each memory circuit. In the capture mode of the scan test, the control circuit enables the corresponding memory circuit according to the clock signal corresponding to each memory circuit to obtain the scan test result.

It should be noted that in the flowchart of FIG. 3, the steps performed by the processing circuit can be executed by different devices, that is, the processing circuit 140 is not limited to a single circuit device. For example, the processing circuit 140 may include a first device and a second device, wherein the first device generates the constraint data Scon, and the second device then generates the test signal Spt and the control signal Sctr according to the constraint data Scon.

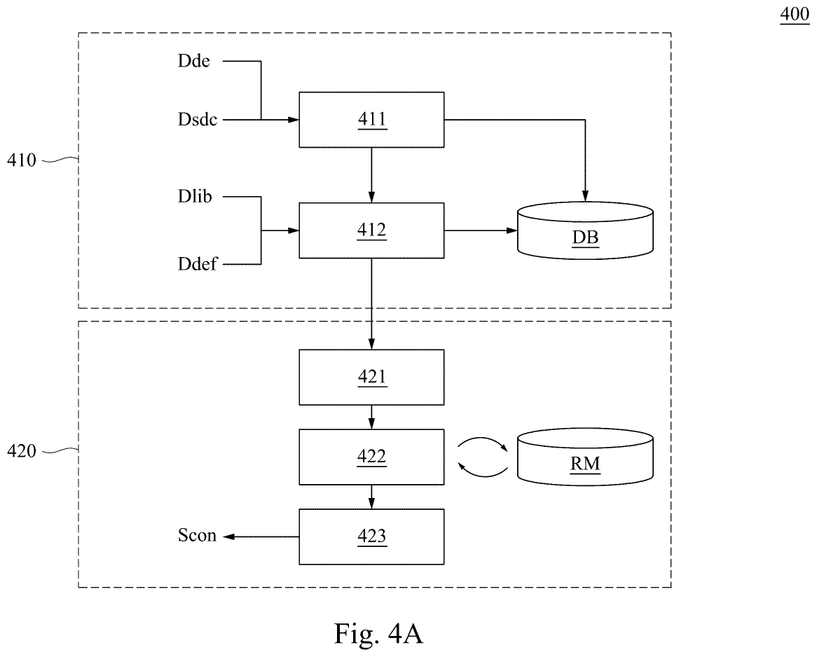

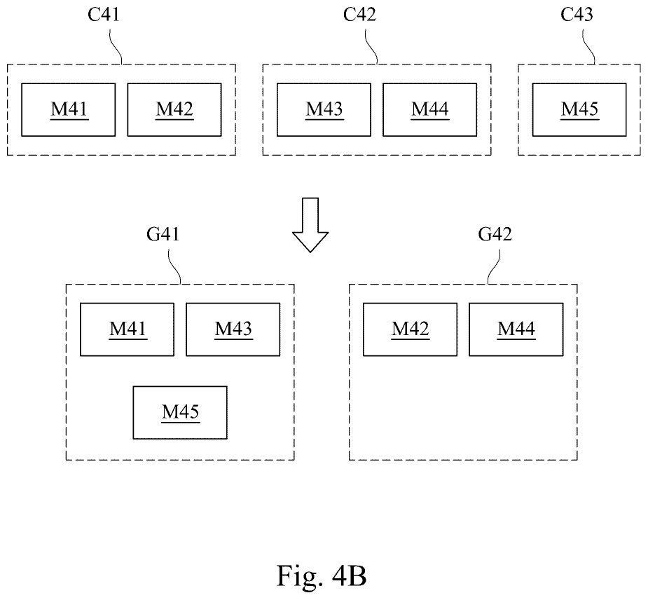

From a different perspective, the followings explains the operation of the present disclosure. FIG. 4A is a schematic diagram of the operation of the processing circuit 400 in some embodiments of the present disclosure. The processing circuit 400 can be applied to implement the processing circuit 140 in FIG. 1 or the processing circuit 240 in FIG. 2. The processing circuit 400 executes a data establishment procedure 410 to generate the analysis result and performs a memory analysis procedure 420 to generate the constraint data Scon.

As shown in FIG. 4A, the data establishment procedure 410 includes a clock analysis 411 and a memory feature analysis 412. During the clock analysis 411, the processing circuit 400 receives the netlist data Dde and the timing constraints data Dsdc to analyze the test modes corresponding to multiple memory circuits or analyze the time domains of multiple clock signals corresponding to the memory circuits.

During the memory feature analysis 412, the processing circuit 400 receives the library data Dlib and the design exchange format data Ddef to obtain the circuit characteristic of the integrated circuit. Specifically, the processing circuit 400 analyzes the layout design, component positions, and connection paths of the integrated circuit to used as the basis for subsequent classification or clustering. The processing circuit 400 records the analysis data generated from the clock analysis 411 and the memory feature analysis 412 into the database DB.

The memory analysis procedure 420 includes a memory classification 421, a memory cluster 422 and a constraint data generation 423. During the memory classification 421, the processing circuit 400 classifies the memory circuits according to the analysis data obtained from the data establishment procedure 410. Specifically, the processing circuit 400 classifies each memory circuit according to the time domain of the clock signal or the test mode corresponding to each memory circuit, classifying each memory circuit to one of multiple test categories. For example, memory circuits belonging to the same time domain (i.e., a portion of all memory circuits) are classified into the same test category.

During the memory clustering 422, the processing circuit 400 clusters the memory circuits according to the test data, the analysis data and the classifying result obtained from the data establishment procedure 410. Specifically, in one embodiment, the processing circuit 400 clusters each memory circuit into one of multiple test groups according to the physical locations of the memory circuits in the integrated circuit. In another embodiment, the processing circuit 400 clusters the memory circuits (i.e., a portion of memory circuits) belonging to different ones of the time domains into the same test group according to the classifying result (i.e., test categories) from memory classification 421. The classifying result and clustering result are recorded in the regression model RM within the processing circuit 400 to record and update each analysis result.

During the constraint data generation 423, the processing circuit 400 generates the constraint data according to the previously obtained classification result and clustering result. This constraint data is used to generate the test signal and control signal. In other words, the test signal and the control signal used in the scan test can be generated according to characteristics such as the physical location, time domain, or test mode of the memory circuits.

To facilitate understanding, FIG. 4B shows a schematic illustration of the classification and clustering. In one embodiment, the integrated circuit includes multiple memory circuits M41-M45. During the memory classification 421, the processing circuit 400 classifies the memory circuits M41-M45 according to the time domain of the clock signal or the test mode, classifying the memory circuits M41-M45 to multiple test categories C41-C43. For example, the same clock signals of the memory circuits M41 and M42 belong to the same time domain, so the memory circuits M41 and M42 are classified into the same test category C41.

As mentioned above, during the memory clustering 422, the processing circuit 400 clusters the memory circuits M41-M45 according to the classifying result. That is, the processing circuit 400 controls the number of memory circuits enabled simultaneously of the same test group. As shown in FIG. 4B, the memory circuits M41-M45 are clustered into multiple test groups G41-G42, ensuring that within each test group, multiple memory circuits are not enabled simultaneously.

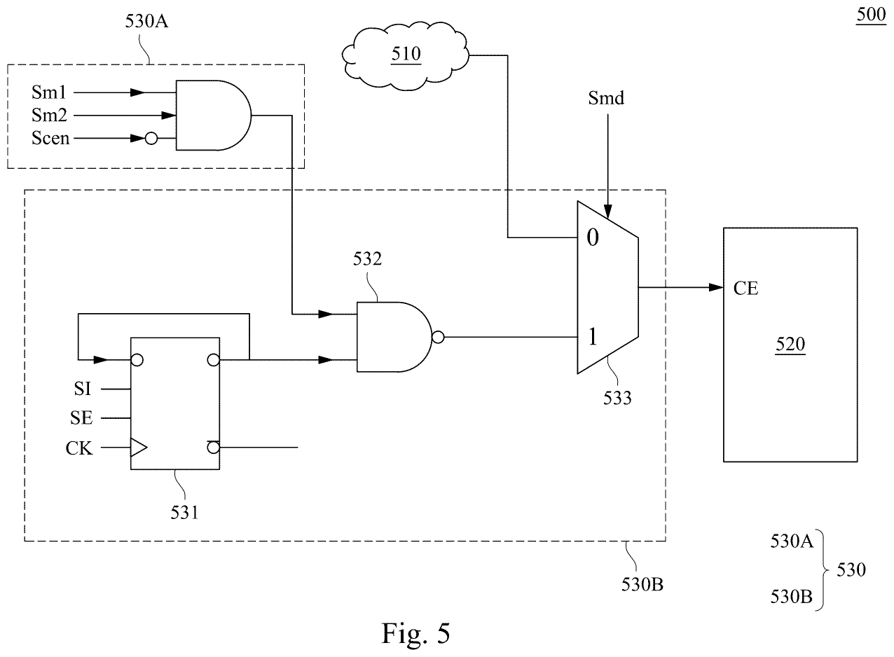

The control circuit in the present disclosure can be adjusted according to requirements and is not limited to the circuit shown in FIG. 2. FIG. 5 is a schematic diagram of the circuit testing system 500 in some embodiments of the present disclosure. The circuit testing system 500 includes a logic circuit 510, a memory circuit 520 and a control circuit 530. The logic circuit and the control circuit 530 are respectively coupled to different input terminals or control terminals of the memory circuit 520. Similar to FIG. 2, the circuit testing system 500 in FIG. 5 can be applied to the integrated circuit shown in FIG. 1. Since the embodiment in FIG. 5 does not change the operation or circuit in which the logic circuit 110A receives the test signal Spt, some circuit elements are omitted in FIG. 5, focusing instead on the relative relationship between the control circuit 530 and the enabling control terminal CE of the memory circuit 520.

As shown in FIG. 5, the control circuit 530 includes a mode control circuit 530A and an enabling control circuit 530B. The mode control circuit 530A is coupled to the enabling control terminal CE of the memory circuit through the enabling control circuit 530B, and is configured to selective enable or disable of the corresponding one of the memory circuits (i.e., memory circuit 520). Specifically, the mode control circuit 530A includes at least one logic element (e.g., an AND gate), and is configured to receive multiple control signals, such as mode signals Sm1/Sm2 and enable signal Scen, in order to generate an enabling control signal.

The enabling control circuit 530B is coupled to the mode control circuit 530A and the enabling control terminal CE of the memory circuit 520, and includes a register 531, a logic element 532, and a multiplexer 533. The register 531 receives the input signal SI and the enable signal SE, and outputs the stored data according to the clock signal CK. The logic element 532 receives the stored data output from the register 531 and the enabling control signal generated by the mode control circuit 530A. The multiplexer 533 is coupled to the logic circuit 510 and the logic element 532, and outputs the signal provided by the logic circuit 510 or the logic element 532 according to the scan mode signal Smd, so as to selectively set the memory circuit 520 in the read mode or the write mode.

In one embodiment, the logic circuit architecture of the control circuit can be determined according to the type of memory circuit. For example, the logic elements of the control circuit can be determined according to the analysis result of the data establishment procedure 410.

In some embodiments, by using the existing memory circuits within the integrated circuit as memory to read the scan test result, the coverage of the scan test can be enhanced, and the IR drop issue that affects the performance of the circuit can be effectively avoided. Accordingly, not only can the coverage of the scan test be improved, but the circuit layout cost of the scan test can also be optimized.

The elements, method steps, or technical features in the foregoing embodiments may be combined with each other, and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A circuit testing method, comprising:
obtaining a test data of an integrated circuit, wherein the integrated circuit comprises a plurality of logic circuits and a plurality of memory circuits, and the test data is configured to record at least one test feature of the plurality of logic circuits and the plurality of memory circuits when performing a scan test;
analyzing the test data to cluster each of the plurality of memory circuits into one of a plurality of test groups, wherein a plurality of first memory circuits of the plurality of memory circuits is clustered into a first test group of the plurality of test groups; and
generating a test signal and a plurality of control signals according to a clustering result of the plurality of memory circuits and the test data, wherein the test signal is configured to perform the scan test on the integrated circuit, the plurality of control signals are configured to control the plurality of first memory circuits, so that when performing the scan test, a number of the plurality of first memory circuits enabled simultaneously is limited to be less than a first enable count limit.

2. The circuit testing method of claim 1, wherein analyzing the test data to cluster each of the plurality of memory circuits into one of the plurality of test groups comprises:
clustering each of the plurality of memory circuits into one of the plurality of test groups according to a plurality of physical locations of the plurality of memory circuits.

3. The circuit testing method of claim 1, wherein analyzing the test data to cluster each of the plurality of memory circuits into one of the plurality of test groups comprises:
analyzing a plurality of time domains or a plurality of test modes corresponding to the plurality of memory circuits according to a netlist data or a timing constraints data.

4. The circuit testing method of claim 3, wherein analyzing the test data to cluster each of the plurality of memory circuits into one of the plurality of test groups further comprises:
clustering a portion of the plurality of memory circuits belonging to a same time domain into a same one of a plurality of test categories.

5. The circuit testing method of claim 4, wherein analyzing the test data to cluster each of the plurality of memory circuits into one of the plurality of test groups further comprises:
clustering another portion of the plurality of memory circuits belonging to different ones of the plurality of time domains into a same one of the plurality of test groups.

6. The circuit testing method of claim 1, wherein obtaining the test data of the integrated circuit comprises:
obtaining one or more of a netlist data, a timing constraints data, a library data or a design exchange format data of the integrated circuit;
wherein the netlist data is configured to record a connection relationship between the plurality of logic circuits and the plurality of memory circuits;
wherein the timing constraints data is configured to record a plurality of clocks of the integrated circuit;
wherein the library data is configured to record a logic characteristic or a power consumption of the plurality of memory circuits; and
wherein the design exchange format data is configured to record a layout structure of the integrated circuit.

7. The circuit testing method of claim 1, further comprising:
analyzing a plurality of memory enable count limits of the plurality of test groups according to a plurality of physical areas corresponding the plurality of test groups, wherein the plurality of memory enable count limits comprise the first enable count limit; and
generating a constraint data according to the plurality of memory enable count limits, the clustering result and the test data to generate the plurality of control signals.

8. The circuit testing method of claim 1, further comprising:
in a shift mode of the scan test, disabling the plurality of memory circuits according to a plurality of clock signals corresponding to the plurality of memory circuits; and
in a capture mode of the scan test, enabling the plurality of memory circuits according to the plurality of clock signals corresponding to the plurality of memory circuits.

9. A circuit testing system, comprising:
a plurality of memory circuits respectively clustered into one of a plurality of test groups, wherein a plurality of first memory circuits of the plurality of memory circuits are clustered into a first test group of the plurality of test groups;
a plurality of logic circuits coupled to the plurality of memory circuits; and
a plurality of control circuits coupled to the plurality of memory circuits, wherein each of the plurality of control circuits selectively enables or disables a corresponding one of the plurality of memory circuits;
wherein when performing a scan test, the plurality of control circuits are configured to receive a plurality of control signals to control a number of the plurality of first memory circuits enabled simultaneously is limited to be less than a first enable count limit.

10. The circuit testing system of claim 9, further comprising a processing circuit, wherein the processing circuit is configured to generate the plurality of control signals according to a plurality of physical locations of the plurality of memory circuits.

11. The circuit testing system of claim 9, further comprising a processing circuit, wherein the processing circuit is configured to generate the plurality of control signals, and is further configured for:
analyzing a plurality of time domains or a plurality of test modes corresponding to the plurality of memory circuits according to a netlist data or a timing constraints data.

12. The circuit testing system of claim 11, wherein the processing circuit is further configured for:
clustering a portion of the plurality of memory circuits belonging to a same time domain into a same one of a plurality of test categories.

13. The circuit testing system of claim 12, wherein the processing circuit is further configured for:
clustering another portion of the plurality of memory circuits belonging to different ones of the plurality of time domains into a same one of the plurality of test groups.

14. The circuit testing system of claim 9, further comprising a processing circuit, wherein the processing circuit is configured for:
analyzing a plurality of memory enable count limits of the plurality of test groups according to a plurality of physical areas corresponding the plurality of test groups, wherein the plurality of memory enable count limits comprise the first enable count limit; and
generating a constraint data according to the plurality of memory enable count limits to generate the plurality of control signals.

15. The circuit testing system of claim 9, further comprising a processing circuit configured to obtain one or more of a netlist data, a timing constraints data, a library data or a design exchange format data of the plurality of memory circuits and the plurality of logic circuits to generate the plurality of control signals;
wherein the netlist data is configured to record a connection relationship between the plurality of logic circuits and the plurality of memory circuits;
wherein the timing constraints data is configured to record a plurality of clocks of the plurality of logic circuits and the plurality of memory circuits;
wherein the library data is configured to record a logic characteristic or a power consumption of the plurality of logic circuits and the plurality of memory circuits; and
wherein the design exchange format data is configured to record a layout structure of the plurality of logic circuits and the plurality of memory circuits.

16. The circuit testing system of claim 9, wherein in a shift mode of the scan test, the plurality of control circuits are configured to disable the plurality of memory circuits according to a plurality of clock signals corresponding to the plurality of memory circuits; and
wherein in a capture mode of the scan test, the plurality of control circuits are configured to enable the plurality of memory circuits according to the plurality of clock signals corresponding to the plurality of memory circuits.

17. The circuit testing system of claim 9, wherein each of the plurality of control circuits comprises:
a enabling control circuit coupled to a corresponding one of the plurality of memory circuits, and configured to selectively enable or disable a corresponding one of the plurality of memory circuits; and
a mode control circuit coupled to a corresponding one of the plurality of memory circuits, and configured to selectively set a corresponding one of the plurality of memory circuits in a read mode or a write mode.

18. A circuit testing method, comprising:
obtaining a test data of an integrated circuit, wherein the integrated circuit comprises a plurality of logic circuits and a plurality of memory circuits, and the test data is configured to record at least one test feature of the integrated circuit when performing a scan test;
classifying each of the plurality of memory circuits into one of a plurality of test categories according to the test data, wherein a portion of the plurality of memory circuits belonging to a same time domain into a same one of the plurality of test categories;
clustering each of the plurality of memory circuits into one of a plurality of test groups according to the test data and the plurality of test categories; and
generating a plurality of control signals corresponding to the plurality of memory circuits according to the test data and the plurality of test groups, so that when performing the scan test, an operating state of the plurality of memory circuits is selectively controlled by the plurality of control signals.

19. The circuit testing method of claim 18, wherein classifying each of the plurality of memory circuits into one of the plurality of test categories comprises:
classifying each of the plurality of memory circuits into one of the plurality of test categories according to a plurality of clock signals or plurality of test modes of the plurality of memory circuits.

20. The circuit testing method of claim 18, wherein clustering each of the plurality of memory circuits into one of the plurality of test groups comprises:
clustering each of the plurality of memory circuits into one of the plurality of test groups according to a plurality of physical locations of the plurality of memory circuits.
